(19) United States
(12) Patent Application Publication
(10) Pub. No.: US 2015/0200681 A1
(43) Pub. Date: Jul. 16, 2015

(54) Segmented Digital-To-Analog Converter With Overlapping Segments

(71) Applicant: LSI Corporation, San Jose, CA (US)

(72) Inventor: Abhishek Duggal, Emmaus, PA (US)

(73) Assignee: LSI Corporation, San Jose, CA (US)

(21) Appl. No.: 14/159,480

(22) Filed: Jan. 21, 2014

Related U.S. Application Data
(60) Provisional application No. 61/926,594, filed on Jan. 13, 2014.

(51) Int. Cl. H03M 1/74; H03M 1/10; H03M 1/06

(52) U.S. Cl. CPC H03M 1/74; H03M 1/0617; H03M 1/1033

(57) ABSTRACT

In one embodiment, a segmented digital-to-analog converter (DAC) has two configurations (i.e., sub-DACs) with overlapping operating ranges and a data mapper that maps the digital input signal into two different digital signals, one for each sub-DAC. The currents generated by the sub-DACs are combined and then used to generate the corresponding analog output signal. Because the sub-DACs have overlapping operating ranges, the DAC can be calibrated to account for process variations that result in the actual current ratio between the two sub-DACs being different from the ideal, designed current ratio. Calibration algorithms generate calibration constants that are applied by the data mapper when mapping the digital input signal into the two digital signals respectively applied to the two sub-DACs. In this way, high-precision DACs can be implemented without requiring expensive circuitry to handle undesirable current mismatch resulting from process variations.

### CROSS-REFERENCE TO RELATED APPLICATIONS

This application claims the benefit of the filing date of U.S. provisional application no. 61/926,594, filed on Jan. 13, 2014, the teachings of which are incorporated herein by reference in their entirety.

### BACKGROUND

1. Field of the Invention

The present invention relates to electronics and, more specifically but not exclusively, to segmented digital-to-analog converters.

2. Description of the Related Art

This section introduces aspects that may help facilitate a better understanding of the invention. Accordingly, the statements of this section are to be read in this light and are not to be understood as admissions about what is prior art or what is not prior art.

Digital-to-analog converters (DACs) convert digital input signals into analog output signals. In certain applications, it is desirable to implement DACs having high precision and low cost (e.g., few components for small layout area and low complexity for short development time).

### BRIEF DESCRIPTION OF THE DRAWINGS

Other embodiments of the invention will become more fully apparent from the following detailed description, the appended claims, and the accompanying drawings in which like reference numerals identify similar or identical elements.

FIG. 1 shows a simplified block diagram of a ramp digital-to-analog converter (DAC);

FIG. 2 shows a simplified block diagram of a segmented, ramp DAC;

FIG. 3 shows a simplified block diagram of an exemplary, digitally-assisted, segmented, ramp DAC;

FIG. 4 shows a block diagram of calibration circuitry used to calibrate the DAC of FIG. 3;

FIG. 5 shows a simplified block diagram of another exemplary, digitally-assisted, segmented, ramp DAC; and

FIG. 6 shows a simplified block diagram of an exemplary, digitally-assisted, un-segmented DAC.

### DETAILED DESCRIPTION

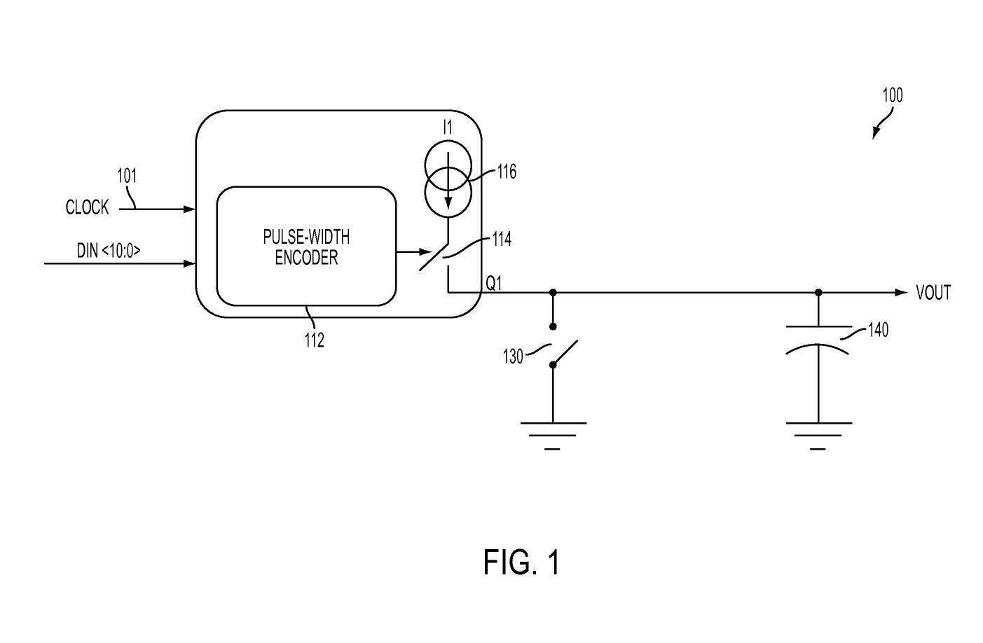

FIG. 1 shows a simplified block diagram of a ramp digital-to-analog converter (DAC) 100 that converts a digital input signal expressed as an 11-bit unsigned binary number Din<10:0> into an analog output signal expressed as a voltage level Vout. In this specification, unless explicitly stated otherwise, all digital signals are assumed to be expressed as binary numbers.

In particular, reset switch 130 is closed to remove any stored charge from capacitor 140 and to initialize the voltage on the top plate of capacitor 140 to ground voltage. Reset switch 130 is then opened to enable DAC 100 to process the next digital input signal Din<10:0>. Pulse-width encoder 112 receives the digital input signal Din<10:0> and a clock signal 101 and generates a pulse in switch-control signal 113 whose duration is equal to the value of Din<10:0> cycles of clock signal 101. Switch-control signal 113 causes switch 114 to be closed for the duration of the pulse. While switch 114 is closed, current I1 flows from constant-current source 116 and accumulates as charge stored in capacitor 140. At the end of the pulse in switch-control signal 113, switch 114 is opened, and the amount of accumulated charge, Q1, stored in capacitor 140 generates an analog output voltage signal, Vout, at the upper plate of capacitor 140. After the analog output voltage signal Vout has been read out from DAC 100, reset switch 130 is closed to remove the charge Q1 from capacitor 140 and reset the DAC prior to the conversion of the next value of Din<10:0>.

DACs with greater precision receive digital input signals having more bits. As the number of bits increases, the amount of time that it takes a ramp DAC, like ramp DAC 100 of FIG. 1, to convert its digital input signal into an analog output signal increases exponentially. To provide fast, high-precision DACs, a segmented architecture may be used.

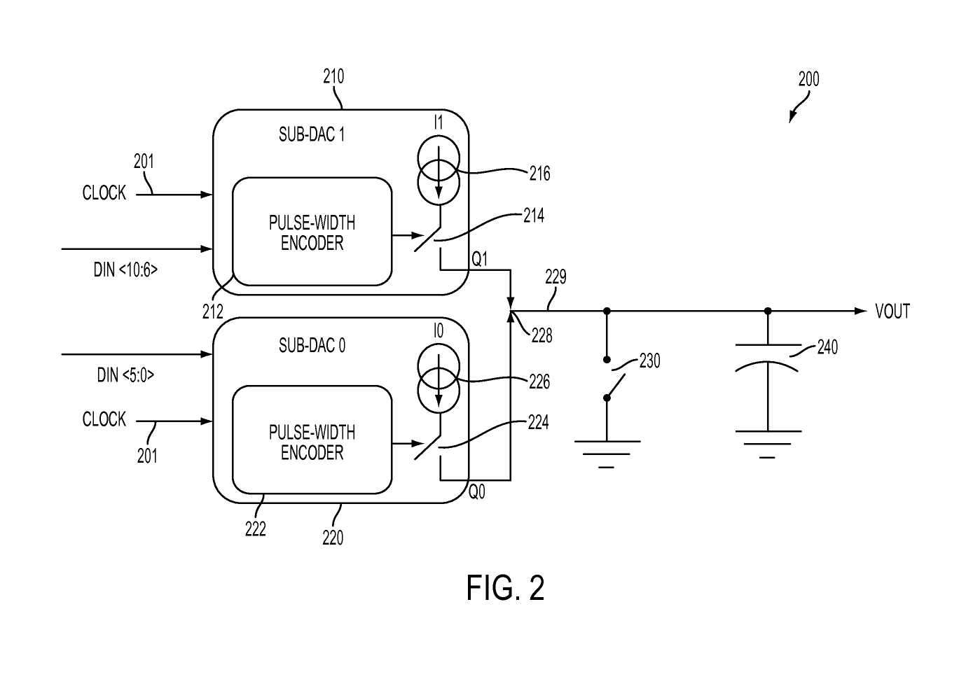

FIG. 2 shows a simplified block diagram of a segmented, ramp DAC 200 that converts an 11-bit digital input signal Din<10:0> into an analog output voltage Vout. Segmented, ramp DAC 200 is similar to ramp DAC 100 of FIG. 1, except that, instead of just a single configuration of a pulse-width encoder, a switch, and a constant-current source, DAC 200 has two such configurations: sub-DAC1 210 for the five MSBs of Din (i.e., Din<10:6>) and sub-DAC0 220 for the six LSBs of Din (i.e., Din<5:0>). Note that subDAC0 and subDAC1, operating concurrently, convert their respective digital inputs into analog charge outputs, Q0 and Q1, respectively. The charge values, Q0 and Q1, are accumulated in capacitor 240, which converts the total charge (Q0+Q1) into an analog output voltage, Vout.

In particular, sub-DAC1 210 outputs current I1 for a duration equivalent to the value of the five-bit binary number Din<10:6> in cycles of clock signal 201, while sub-DAC0 220 outputs current I0 for a duration equivalent to the value of the six-bit binary number Din<5:0> in cycles of clock signal 201. The two current signals are combined at node 228, and the combined current 229 is accumulated as the total charge (Q0+Q1) on the top plate of capacitor 240 to generate analog output voltage Vout after both switches 214 and 224 are eventually opened. Note that, depending on the values of Din<10:6> and Din<5:0>, one current will typically be applied at node 228 longer than the other. Instead of taking Din<10:0> clock cycles to complete the DAC conversion as in FIG. 1, the conversion of FIG. 2 takes the greater of Din<10:6> and Din<5:0> clock cycles to complete, that is, up to 32 times shorter conversion time.

In order for DAC 200 to generate the appropriate analog output voltage with high precision, the minimum (non-zero) output of sub-DAC1 210 (i.e., I1*1 cycle of clock signal 201) should be equal to the maximum output of sub-DACO 220 (i.e., I0*63 cycles of clock signal 201) plus one additional unit of sub-DACO 220 (i.e., I0*1 cycle of clock signal 201). In other words, the magnitude of current I1 should be exactly equal to 64 times the magnitude of I0. Consequently, the performance of DAC 200 is sensitive to precise matching between the I1 and I0 current sources 216 and 226 (to maintain a precise ratio between the magnitudes of the I1 and I0 currents). However, due to process variations, current I1 might not be equal to 64*I0 with sufficient precision. As such, segmented, ramp DACs, like DAC 200 of FIG. 2, are designed with much additional circuitry (not shown in FIG. 2) to compensate for such mismatches, which additional circuitry increases the layout area and cost of these DAC designs.

In general, the conversion gain of a DAC is defined as the ratio of its maximum full-scale analog output voltage (that is obtained when its digital input is maximum) to its maximum digital input. Related to the conversion gain, the LSB size of a DAC is defined as the analog output of the DAC corresponding to the unit digital input. Due to various non-idealities, the LSB size (unit output) of DAC 200 and consequently the conversion gain of DAC 200 will vary from their desired values. As such, DACs, like DAC 200 of FIG. 2, are designed with much additional circuitry (not shown in FIG. 2) to compensate for such LSB size variation, which additional circuitry increases the layout area and cost of these DAC designs.

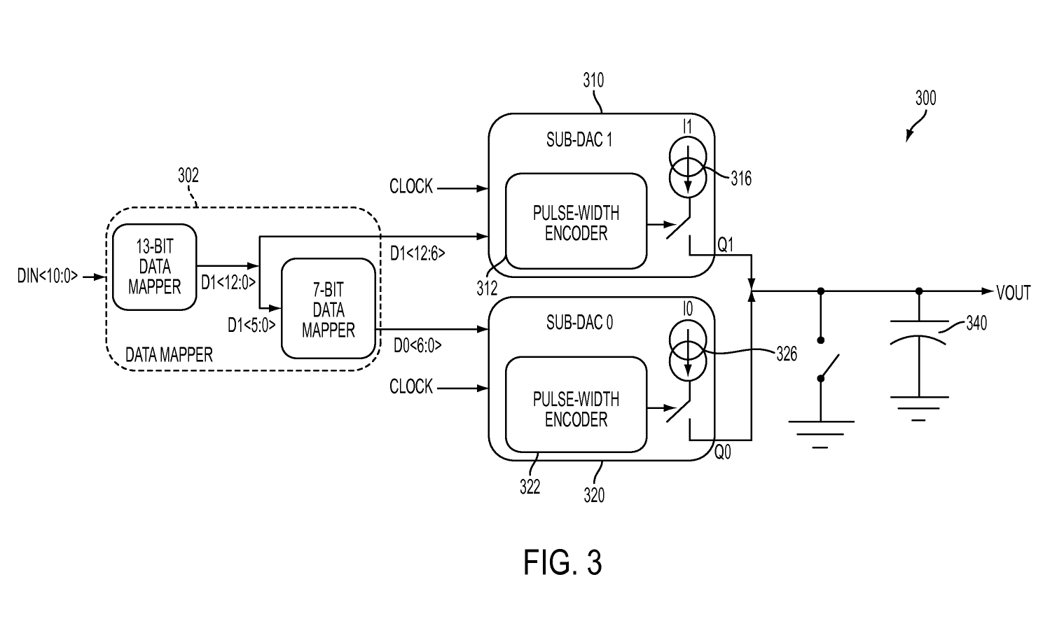

FIG. 3 shows a simplified block diagram of an exemplary, digitally-assisted, segmented, ramp DAC 300 that converts an 11-bit digital input signal Din<10:0> into an analog output voltage Vout. Segmented, ramp DAC 300 is similar to segmented, ramp DAC 200 of FIG. 2, except that, instead of simply feeding the MSB bits of Din to a sub-DAC1 and the LSB bits of Din to a sub-DACO, DAC 300 has a data mapper 302 that maps the bits Din<10:0> into two different digital signals: seven-bit digital signal D1<12:6> and seven-bit digital signal DO<6:0>. Except for the fact that pulse-width encoders 312 and 322 of DAC 300 have different sizes from five-bit pulse-width encoder 212 and six-bit pulse-width encoder 222 of FIG. 2, the rest of DAC 300 operates in an equivalent fashion to the rest of DAC 200 of FIG. 2, with two pulses of constant current I1 and I0 being accumulated as charges Q1 and Q0, respectively, in capacitor 340 and represented as analog output voltage Vout.

As described previously, in an ideal implementation of DAC 200 of FIG. 2, I1 equals 64*I0. Since the largest value of Din<5:0> is [111111] or 63, this means that, in an ideal implementation of DAC 200, the amount of charge that can be applied to capacitor 240 by sub-DACO 220 in 63 clock cycles is less than the amount of charge that can be applied to capacitor 240 by sub-DAC1 210 in only one clock cycle. As such, in DAC 200, there is no intentional, desired overlap in the operating ranges of sub-DAC1 210 and sub-DACO 220. If an overlap does exist in DAC 200, it is due to an undesired mismatch between the two constant-current sources 216 and 226.

In DAC 300 of FIG. 3, however, the magnitudes of currents I1 and I0 from constant-current sources 316 and 326 are specifically selected such that there will be an intentional, desired overlap in the operating ranges of sub-DAC1 310 and sub-DAC0 320. This means that the subDAC0 output charge, Q0, corresponding to its maximum input (D0=[1111111]) is larger than the subDAC1 output charge, Q1, corresponding to its unit input (D1<12:6>=[0000001]). As such, there will be a range of one or more values of digital signal D1<12:6> that causes sub-DAC1 310 to produce a range of analog output charge magnitudes that can also be produced by sub-DACO 320 for a range of one or more values of digital signal D0<6:0>. Note that the operating range of sub-DAC1 310 extends above the operating range of sub-DACO 320 (i.e., sub-DAC1 310 can generate charge magnitudes larger than the maximum charge magnitude that sub-DAC0 320 can), and that the operating range of sub-DAC0 320 extends below the operating range of sub-DAC1 310 (i.e., sub-DACO 320 can generate non-zero charge magnitudes smaller than the minimum non-zero charge magnitude that sub-DAC1 310 can). A constant, Klsb, determined by calibration, represents the largest “non-overlapping” value of the input of the subDAC0, D0<6:0>, in the sense that Klsb is the largest value of D0<6:0> that produces an output charge Q0 that is smaller than the output charge Q1 produced by D1<12:6>=[0000001]. In the embodiment of FIG. 3, the ratio of current magnitude I1 to the current magnitude I0 is allowed to vary in the range {64, 128}. The largest “non-overlapping” input value for subDAC0, Klsb, will consequently vary between DO<6:0>=[0111111] and [1111111] corresponding to the actual ratio of I1 to I0. The data mapper algorithm ensures that during operation, the value of D0<6:0> at the output of the data mapper never exceeds Klsb.

The existence of this intentional overlap between the sub-DACs means that DAC 300 can be operated at high precision even when there is current mismatch due to process variations and possibly other types of variations (e.g., voltage, temperature). In the particular implementation of DAC 300, current mismatch can cause I1 to range anywhere from 64*I0 to 128*I0. Thus, if current sources 316 and 326 are designed such that I1 is ideally equal to 96*I0, then DAC 300 can be operated with high precision even if, due to process variations, the actual ratio of I1:I0 is as low as 64 or as high as 128. The data mapper algorithm corrects for this variation. In alternative implementations, that allowed range can be made larger or smaller.

Although the disclosure has been described in the context of DAC 300, in which the current ratio I1:I0 is allowed to vary in the range {64,128}, it will be obvious to those skilled in the art that the overlapping segments can be alternatively designed such that the ratio of I1 current to I0 current is allowed to vary over only a sub-range of {64,128}, e.g., from 64 to 96. In this alternative embodiment, the value of Klsb will correspondingly vary only between 63 and 95. The data mapper output signal, D0<6:0>, will consequently have a maximum possible value of 95.

Although the disclosure has been described in the context of DAC 300, where D0 is depicted as a 7-bit binary number, those skilled in the art will understand that the allowed range of variation of the ratio of I1 to I0 can be made larger in an alternative embodiment by adding more bits of overlap between subDAC0 and subDAC1, by correspondingly adding bits of resolution to the data mapper and subDAC0, and by having a correspondingly larger number of bits in signal D0. For example, the ratio of I1 to I0 is allowed to vary in the range from 64 to 256 (and Klsb varies between 63 and 255) in an alternative embodiment where the data mapper generates an 8-bit digital signal, D0<7:0>.

Assume a reference voltage, Vfs, that represents the desired full-scale analog output of DAC 200 of FIG. 2. As described previously, in an ideal implementation of DAC 200 of FIG. 2, the full-scale analog output (corresponding to the maximum digital input) is exactly equal to the desired full-scale voltage, Vfs. In DAC 200, there is no intentional, desired overlap in the full-scale analog output and Vfs. If the full-scale analog output does exceed Vfs in DAC 200, it is due to undesired variation in the DAC conversion gain and LSB size from their ideal values.

In DAC 300 of FIG. 3, however, the full-scale analog output is designed to intentionally overlap with the reference voltage, Vfs, in the sense that the analog output voltage corresponding to the maximum digital signal D1<12:0> is larger than the reference voltage, Vfs. A constant, Kfs, determined by calibration, represents the largest non-overlapping value of the digital signal, D1<12:0>, in the sense that Kfs is equal to the largest value of D1<12:0> that produces an analog output voltage that is smaller than Vfs. In the embodiment of FIG. 3, the full-scale analog output corresponding to the full range of digital signal, D1<12:0>, is allowed to vary in the range between Vfs and 2*Vfs. The value of Kfs correspondingly varies between [0111111111111] and [1111111111111]. The method of certain embodiments of this invention corrects for this variation in subDAC1 module 310 and provides a precisely controlled full-scale analog output, equal to Vfs, for DAC 300. The data mapper algorithm ensures that, during operation, the value of the digital signal, D1<12:0>, never exceeds Kfs,

Although this disclosure has been described in the context of DAC 300 where the full-scale analog output of subDAC1 310 is allowed to vary in the range between Vfs and 2*Vfs, it will be obvious to those skilled in the art that, in alternative embodiments, this allowed range can be larger or smaller.

Note that, in DAC 200 of FIG. 2, the sum of (i) the number of bits in Din<10:6>, which is applied to sub-DAC1 210, (i.e., five) and (ii) the number of bits in Din<5:0>, which is applied to sub-DACO 220, (i.e., six) is equal to the number of bits in Din<10:0> (i.e., eleven). In DAC 300 of FIG. 3, however, the sum of (i) the number of bits in D1<12:6>, which is applied to sub-DAC1 310, (i.e., seven) and (ii) the number of bits in DO<6:0>, which is applied to sub-DACO 320, (i.e., seven) is greater than the number of bits in Din<10:0> (i.e., eleven). The embodiment in FIG. 3 is a composite of three ideas that, in alternative embodiments, may be applied separately or in various combinations:
a. Overlapping segments to reduce mismatch sensitivity;
b. Overlapping between DAC output and desired full-scale reference, Vfs; and
c. Adding one or more bits of resolution to subDAC0 to reduce numerical error.

In the embodiment of FIG. 3, all three methods listed above are combined such that each method adds one bit to the sum of the subDAC segments relative to the DAC input, Din<10:0>. One of the three extra bits in DAC 300 is used to overlap the segments, subDAC0 and subDAC1, in order to reduce sensitivity to mismatch between the current sources in the segments, subDAC0 and subDAC1. A second extra bit is used to overlap the full-scale analog output of subDAC1 and the desired full-scale output, Vfs, in order to reduce sensitivity to the variation of subDAC1 LSB size and conversion gain. The data mapper arithmetic has precision equal to 1 LSB of the subDAC0. Consequently, numerical error from data mapper computations is limited to within +/−0.5 LSB of sub-DAC0. The third extra bit is used to reduce the LSB size of subDAC0 relative to the LSB size of DAC 300 in order to reduce the numerical error from the data mapper computations. In the embodiment of FIG. 3, the LSB size of subDAC0 is half of the LSB size of DAC 300. Hence, numerical error from data mapper computations is limited to within +/−0.25 LSB of DAC 300.

The following data-mapping algorithm describes how data mapper 302 generates the two digital signals D1<12:6> and D0<6:0> from the 11-bit, binary, digital input signal Din<10:0>, using the constants, Kfs and Klsb, determined by calibration:
1) Calculate D1<12:0>=Din<10:0>*Kfs<12:0>/[11111111111], where the result is truncated to 13 bits to fit in D1<12:0>.
2) Use D1<12:6> to generate the charge pulse for sub-DAC1 310.
3) Calculate D0<6:0>=D1<5:0>*Klsb<6:0>/[111111], where the result is truncated to 7 bits to fit in D0<6:0>.
4) Use D0<6:0> to generate the charge pulse for sub-DACO 320.

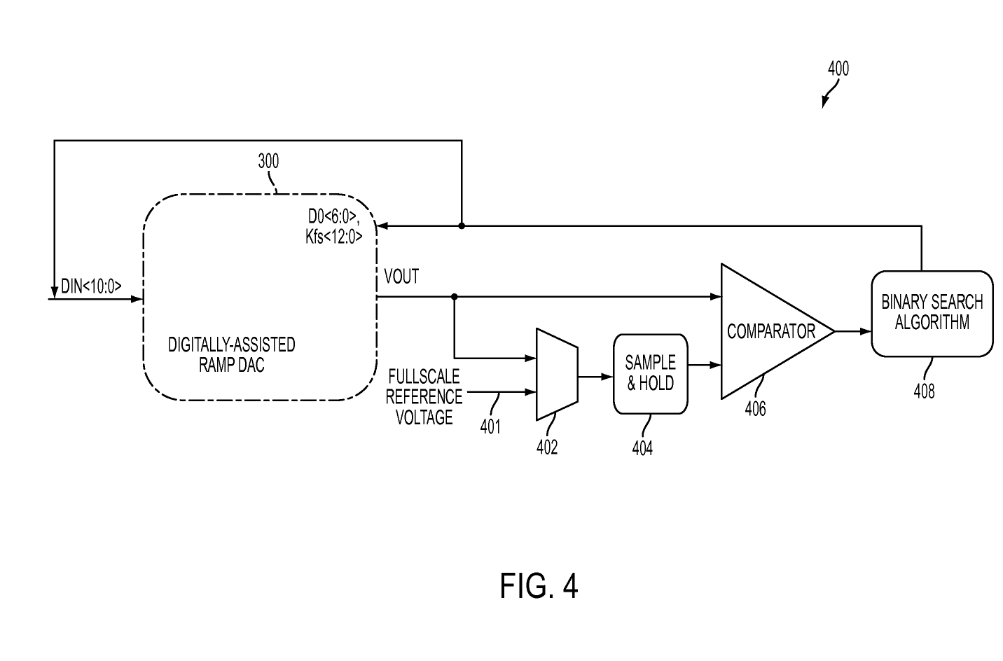

FIG. 4 shows a block diagram of calibration circuitry 400 used to generate the values of calibration constants Kfs<12:0> and Klsb<6:0> used by digital mapper 302 to generate digital signals D1<12:6> and D0<6:0> from digital input signal Din<10:0>. Calibration circuitry 400 includes 2:1 multiplexer (mux) 402, sample-and-hold (S&H) circuit 404, comparator 406, and search processor 408. The operations of calibration circuitry 400 will be explained in the context of two different calibration algorithms: (i) a current-ratio calibration algorithm to generate a value for the 7-bit current-ratio calibration constant Klsb<6:0>, which calibrates for current mismatch between I0 and I1, and (ii) a full-scale calibration algorithm to generate a value for the 13-bit full-scale calibration constant Kfs<12:0>, which calibrates for the maximum output of DAC 300.

The current-ratio calibration algorithm used to generate a value for the 7-bit current-ratio calibration constant Klsb<6:0> is as follows:
1) Apply D1<12:6>=[0000001] at the input of sub-DAC1 310 (with D0=0) and store the DAC output voltage with the sample & hold circuit 404.

2) Using comparator 406 to compare the output voltage of DAC 300 with the voltage stored in the sample & hold circuit 404, perform a binary search in the range of values between [1000000] and [1111111] for D0<6:0> at the input of DAC (with D1<12:6>=0) to find the DAC output voltage that is closest to the previously stored voltage.
3) Klsb<6:0>=[(Binary search result)−1].

The full-scale calibration algorithm used to generate a value for the 13-bit full-scale calibration constant Kfs<12:0> is as follows:
1) Store the full-scale reference voltage 401 with the sample & hold circuit 404.
2) Set Din<10:0>=[11111111111].
3) Using comparator 406 to compare the output voltage of DAC 300 with the voltage stored in the sample & hold circuit 404, perform a binary search in the range of values between [0111111111111] and [1111111111111] to find the value of Kfs<12:0> that produces a DAC output voltage that is closest to the previously stored voltage.
4) Kfs<12:0>=Binary search result.

The two generated values for the calibration constants Klsb<6:0> and Kfs<12:0> are then used by DAC 300 during normal, real-time operations to convert digital input signals Din into analog output voltages Vout. Note that one or both calibration algorithms can be repeated periodically or intermittently, as needed or desired, e.g., every time DAC 300 is powered up.

Although the disclosure has been described in the context of DAC 300 of FIG. 3, which has an 11-bit digital input signal Din that is mapped to two 7-bit digital signals D1<12:6> and D0<6:0> that support a range of current ratios I1:I0 from 64 to 128, those skilled in the art will understand that, in other implementations, the digital input signal Din may have any other suitable number of bits and/or Din may be mapped to two digital signals, each having a (possibly different) number of bits other than seven and supporting a possibly different current ratio range.

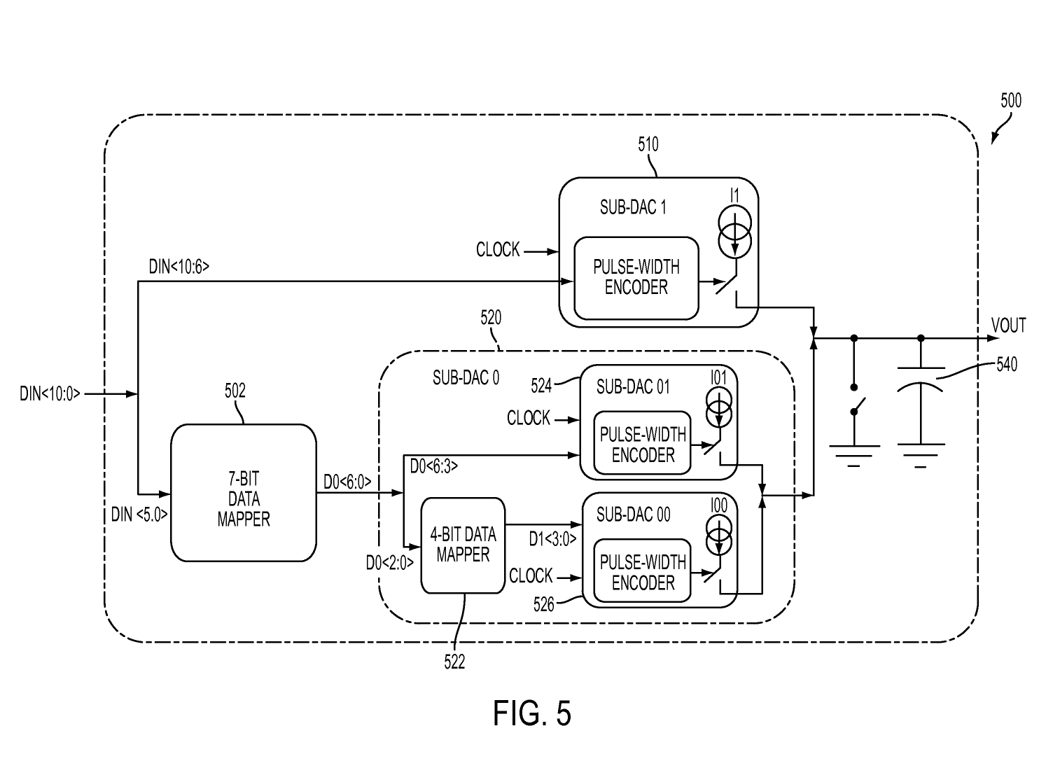

Although the disclosure has been described in the context of ramp DACs, the digitally-assisted “overlapping” segmentation scheme can be applied in the context of other types of DACs as well, such as current-steering DACs or capacitor DACs. Note that each different sub-DAC may be independently implemented using any suitable type of DAC circuitry. For example, in FIG. 5, sub-DAC1 510 could be implemented using ramp DAC circuitry, while sub-DAC01 524 is implemented using binary-weighted array, current-steering DAC circuitry, and sub-DAC00 526 is implemented using unit-element array, current-steering DAC circuitry.

Although the disclosure has been described in the context of specific data mapper algorithms, the scope of the invention is not so limited. Knowledge of the calibration constant Klsb can be used by upstream signal-processing circuits to optimize the sub-DAC input values in other ways that are useful to the specific application. The resolution of a generic, segmented DAC with overlapping segments depends on the value of Klsb. For example, assume that a DAC (not shown) is implemented with two 6-bit segments, 6-bit subDAC0 and 6-bit subDAC1, such that the ratio of LSB magnitudes of sub-DAC-1 and sub-DAC-0 varies within a range of 32 to 64. Consequently, the value of Klsb for this exemplary DAC will be between 31 and 63. In this case, the resolution of the DAC is a real number >=11 bits and <12 bits. In comparison with sub-DAC1 210 in the traditional segmented DAC 200 of FIG. 2, sub-DAC1 in the exemplary, digitally-assisted, overlapping, segmented DAC has one extra bit of resolution, and the overall resolution of the DAC is at least as high as the overall resolution of the traditional segmented DAC 200. The insensitivity to mismatch between sub-DAC1 and sub-DAC0 allows the exemplary DAC to be much smaller in layout area than the traditional segmented DAC 200.

Furthermore, although the disclosure has been described in the context of DAC 300 of FIG. 3, which has two overlapping sub-DACs, those skilled in the art will understand that, in other embodiments, a DAC may have three or more sub-DACs consisting of an instance of sub-DAC1, an instance of sub-DAC0, and one or more intermediate sub-DACs, where at least one pair of “adjacent” sub-DACs (and possibly as many as each and every pair of adjacent sub-DACs) overlap in their respective operating ranges.

As described previously, the exemplary embodiment of FIG. 3 embodies the following three features:
Using one or more additional bits to provide overlapping sub-DAC segments to reduce sensitivity to variation of current ratio;
Using one or more additional bits to overlap the full-scale analog output and the desired full-scale output in order to reduce sensitivity to variation of LSB size and conversion gain; and
Using one or more additional bits to reduce numerical error.

The first feature, overlapping segmentation, can be applied recursively to obtain more than two overlapping segments. This feature can then be implemented by itself or combined with one or both of the other two features.

FIG. 5 shows a simplified block diagram of another exemplary, digitally-assisted, overlapping, segmented, ramp DAC 500 that converts an 11-bit digital input signal Din<10:0> into an analog output voltage Vout. As shown in FIG. 5, the architecture of DAC 500 is based on the fact that the digitally-assisted, overlapping, segmented architecture can be applied recursively. In particular, in FIG. 5, overlapping segmentation is applied first to DAC 500 to provide a first digitally-assisted, overlapping, segmented architecture comprising data mapper 502, sub-DAC1 510, and sub-DAC0 520, where one extra bit is used to provide overlap between the two segments. A constant K0, determined by calibration, represents the largest non-overlapping value at the input, D0<6:0>, of subDAC0 520. In addition, overlapping segmentation is then applied to sub-DAC0 520 to provide a second digitally-assisted, overlapping, segmented architecture comprising data mapper 522, sub-DAC01 524, and sub-DAC00 526, where another extra bit is used to provide overlap between these two segments. A constant K1, determined by calibration, represents the largest non-overlapping value at the input, D1<3:0>, of subDAC00 526.

In operation, the five MSBs Din<10:6> are applied directly to sub-DAC1 510, while the six LSBs Din<5:0> are applied to 7-bit data mapper 502, which converts 6-bit Din<5:0> into 7-bit D0<6:0> as follows:

D0<6:0>=Din<5:0>*K0<6:0>/[111111],

where K0<6:0> is a first current-ratio calibration constant, and the result is truncated to seven bits to fit into D0<6:0>, which is then applied to sub-DAC0 520.

The four MSBs D0<6:3> are then applied directly to sub-DAC01 524, while the three LSBs D0<2:0> are applied to 4-bit data mapper 522, which converts 3-bit D0<2:0> into 4-bit D1<3:0> as follows:

D1<3:0>=D0<2:0>*K1<3:0>/[111],

where K1<3:0> is a second current-ratio calibration constant, and the result is truncated to four bits to fit into D1<3:0>, which is then applied to sub-DAC00 526.

Note that, in this exemplary embodiment, sub-DAC1 510 overlaps with sub-DACO 520, and sub-DAC01 524 overlaps with sub-DAC00 526. In theory, the recursion of FIG. 5 can be applied any available number of times to any of the sub-DACs of DAC 500. Each pair of overlapping segments will have its own corresponding current-ratio calibration constant determined by calibration. Knowledge of the calibration constants for all the overlapping segment pairs can be used by upstream signal-processing circuits to optimize the sub-DAC input values.

Although the disclosure has been described in the context of segmented DACs having two or more sub-DACs that generate charge magnitudes that are combined to generate an output voltage signal, those skilled in the art will understand that, in other embodiments, segmented DACs can be configured to generate an output current signal (instead of an output voltage signal) or with sub-DACs that generate voltages (instead of currents) that are combined to generate the analog output signal.

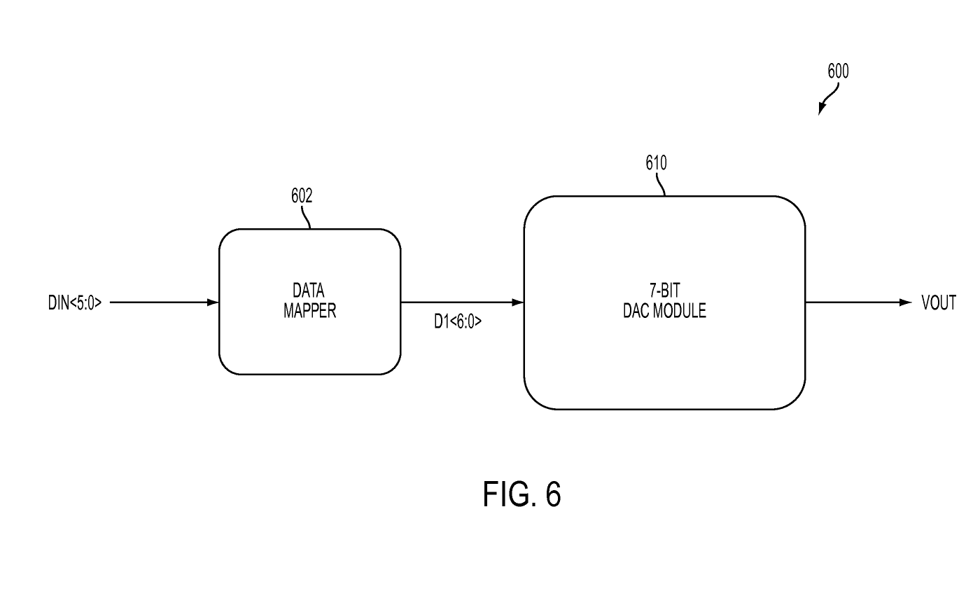

Although full-scale analog output precision control has been described in the context of a digitally-assisted, segmented, ramp DAC, the full-scale control method of this disclosure is broadly applicable to all types of DACs, whether segmented or not, as generally represented in FIG. 6.

For a general DAC, its conversion gain is defined as the ratio of its maximum full-scale analog output voltage (that is obtained when its digital input is maximum) to its maximum digital input. Due to various non-idealities, the conversion gain of a DAC will vary from its desired value. FIG. 6 represents a method to correct for this variation and thereby to control the DAC conversion gain and full-scale analog output such that they precisely match the desired values.

FIG. 6 shows a simplified block diagram of an exemplary digitally-assisted, un-segmented 6-bit DAC 600 that converts a 6-bit digital input signal Din<5:0> into an analog output voltage Vout. DAC 600 includes a data mapper 602 that converts the 6-bit digital input signal Din<5:0> into a 7-bit digital signal D1<6:0> that gets applied to a 7-bit DAC module 610, which generates the analog output voltage Vout.

Assume a reference voltage, Vfs, that represents the desired full-scale analog output of 6-bit DAC 600. The 7-bit DAC module 610 is designed to intentionally overlap with the reference voltage, Vfs, in the sense that the analog output corresponding to the maximum digital input of DAC module 610 is larger than the reference voltage, Vfs. A constant, Kfs, determined by calibration, represents the largest non-overlapping value of the input of DAC module 610, D1<6:0>, such that Kfs is the largest value of D1<6:0> that produces an analog output that is smaller than Vfs. In this embodiment, the full-scale analog output of DAC module 610 is allowed to vary in the range between Vfs and 2*Vfs. The value of Kfs correspondingly varies between 63 and 127. The method of certain embodiments of this invention corrects for this variation in DAC module 610 and provides a precisely controlled full-scale analog output, equal to Vfs, for DAC 600. The data mapper algorithm ensures that during operation, the value of the signal D1<6:0> never exceeds Kfs.

The following data-mapping algorithm describes how the 7-bit data mapper 602 in FIG. 6 generates the digital signal D1<6:0> from the digital input signal Din<5:0> using the calibration constant, Kfs:

Calculate D1<6:0>=Din<5:0>*Kfs<6:0>/[111111]. The result of the calculation is truncated to 7-bit precision to fit in D1<6:0>.

The full-scale calibration constant Kfs is calibrated as follows:
1) Use a reference analog voltage, Vfs, that represents the desired full-scale analog output of DAC 600.

2) Perform a binary search in the range of values between [0111111] and [1111111] for D1<6:0> at the input of DAC module 610 to find the DAC output voltage that is closest to the reference voltage, Vfs (e.g., using a comparator (not shown) to compare the two analog voltages).
3) Kfs<6:0>=Binary search result.

Embodiments of the invention may be implemented as differential circuits, wherein every analog signal in the design is implemented as a pair of differential signals

Embodiments of the invention may be implemented as (analog, digital, or a hybrid of both analog and digital) circuit-based processes, including possible implementation as a single integrated circuit (such as an ASIC or an FPGA), a multi-chip module, a single card, or a multi-card circuit pack. As would be apparent to one skilled in the art, various functions of circuit elements, such as those associated with search processor 408 of FIG. 4, may also be implemented as processing blocks in a software program. Such software may be employed in, for example, a digital signal processor, micro-controller, general-purpose computer, or other processor.

Also for purposes of this description, the terms “couple,” “coupling,” “coupled,” “connect,” “connecting,” or “connected” refer to any manner known in the art or later developed in which energy is allowed to be transferred between two or more elements, and the interposition of one or more additional elements is contemplated, although not required. Conversely, the terms “directly coupled,” “directly connected,” etc., imply the absence of such additional elements.

Signals and corresponding nodes, ports, or paths may be referred to by the same name and are interchangeable for purposes here.

It should be appreciated by those of ordinary skill in the art that any block diagrams herein represent conceptual views of illustrative circuitry embodying the principles of the invention. Similarly, it will be appreciated that any flow charts, flow diagrams, state transition diagrams, pseudo code, and the like represent various processes which may be substantially represented in computer readable medium and so executed by a computer or processor, whether or not such computer or processor is explicitly shown.

Digital information can be transmitted over virtually any channel. Transmission applications or media include, but are not limited to, coaxial cable, twisted pair conductors, optical fiber, radio frequency channels, wired or wireless local area networks, digital subscriber line technologies, wireless cellular, Ethernet over any medium such as copper or optical fiber, cable channels such as cable television, and Earth-satellite communications.

Unless explicitly stated otherwise, each numerical value and range should be interpreted as being approximate as if the word “about” or “approximately” preceded the value or range.

It will be further understood that various changes in the details, materials, and arrangements of the parts which have been described and illustrated in order to explain embodiments of this invention may be made by those skilled in the art without departing from embodiments of the invention encompassed by the following claims.

The use of figure numbers and/or figure reference labels in the claims is intended to identify one or more possible embodiments of the claimed subject matter in order to facilitate the interpretation of the claims. Such use is not to be construed as necessarily limiting the scope of those claims to the embodiments shown in the corresponding figures.

It should be understood that the steps of the exemplary methods set forth herein are not necessarily required to be performed in the order described, and the order of the steps of such methods should be understood to be merely exemplary. Likewise, additional steps may be included in such methods, and certain steps may be omitted or combined, in methods consistent with various embodiments of the invention.

Although the elements in the following method claims, if any, are recited in a particular sequence with corresponding labeling, unless the claim recitations otherwise imply a particular sequence for implementing some or all of those elements, those elements are not necessarily intended to be limited to being implemented in that particular sequence.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

The embodiments covered by the claims in this application are limited to embodiments that (1) are enabled by this specification and (2) correspond to statutory subject matter. Non-enabled embodiments and embodiments that correspond to non-statutory subject matter are explicitly disclaimed even if they fall within the scope of the claims.

What is claimed is:

1. A segmented digital-to-analog converter for converting a digital input signal into an analog output signal, the converter comprising:
a first sub-converter capable of generating a first sub-converter range of possible analog signal magnitudes and configured to convert a first digital signal, based on the digital input signal, into a first analog signal within the first range;
a second sub-converter capable of generating a second sub-converter range of possible analog signal magnitudes and configured to convert a second digital signal, based on the digital input signal, into a second analog signal within the second sub-converter range, wherein the second sub-converter range overlaps with the first sub-converter range; and
a combiner configured to combine the first and second analog signals to generate the analog output signal.

2. The converter of claim 1, wherein:
the first sub-converter is capable of generating a smallest non-zero value of the first analog signal;
the second sub-converter is capable of generating a largest non-overlapping value of the second analog signal that is smaller than the smallest non-zero value of the first analog signal; and
the converter ensures that, during operation, the second sub-converter does not generate a second analog signal that exceeds the largest non-overlapping value.

3. The converter of claim 1, wherein:
the digital input signal is an N-bit binary value;
the first digital signal is a P-bit binary value; and
the second digital signal is a Q-bit binary value, where N, P, and Q are integers and (P+Q)>N;

4. The converter of claim 1, wherein:
the first sub-converter range extends above the second sub-converter range; and
the second sub-converter range extends below the first sub-converter range.

5. The converter of claim 1, wherein the first and second converters are ramp converters.

6. The converter of claim 1, wherein the converter is configured to use one or more calibration constants to generate the first and second digital values from the digital input value.

7. The converter of claim 6, wherein:
a first calibration constant is a current-ratio calibration constant that calibrates for current mismatch between the first and second sub-converters.

8. The converter of claim 7, wherein:
a second calibration constant is a full-scale calibration constant that calibrates for maximum output of the converter.

9. The converter of claim 1, wherein at least one of the first and second sub-converters is itself implemented using one or more recursive instances of the first and second sub-converters, and the combiner.

10. The converter of claim 1, wherein the converter adds one or more bits to reduce numerical error.

11. The converter of claim 1, wherein the converter adds one or more bits for full-scale magnitude control.

12. The converter of claim 11, wherein the converter adds one or more bits to reduce numerical error.

13. A method for calibrating the converter of claim 7, the method comprising:
(a) operating the converter with calibration circuitry to generate a calibrated value for the current-ratio calibration constant.

14. The method of claim 13, wherein step (a) comprises:
(a1) generating a first analog output signal with the first and second digital signals set to first and second specified values;
(a2) generating a second analog output signal with the first digital signal set to the first specified value by searching for a final digital value for the second digital signal that generates the second analog output signal substantially equal to the first analog output signal; and
(a3) calculating the calibrated value for the current-ratio calibration constant based on the final digital value for the second digital signal; and

15. The method of claim 13, further comprising:
(b) operating the converter with the calibration circuitry to generate a calibrated value for a full-scale calibration constant that calibrates for maximum output of the converter.

16. The method of claim 15, wherein step (b) comprises:
(b1) generating a third analog output signal with the digital input signal set to its maximum value and the current-ratio calibration constant set to its calibrated value by searching for a final value for the full-scale calibration constant that generates the third analog output signal substantially equal to a full-scale reference voltage for the converter.

17. A digital-to-analog converter system for converting a digital input signal into an analog output signal, the converter system comprising:
a data mapper configured to convert the digital input signal into a first digital signal having one or more additional bits;
a digital-to-analog converter module configured to convert the first digital signal into the analog output signal; and
calibration circuitry configured to calibrate the converter system based on an applied full-scale analog reference signal, wherein at least one of the one or more additional bits is used to enable the analog output signal corresponding to a maximum value for the digital input signal to be substantially equal to the full-scale analog reference signal.

18. The converter system of claim 17, wherein:
the digital-to-analog converter system is a segmented digital-to-analog converter comprising first and second sub-converters having respective first and second sub-converter ranges; and
at least one of the one or more additional bits is used to enable the second sub-converter range to overlap with the first sub-converter range.

19. The converter system of claim 17, wherein at least one of the one or more additional bits is used to reduce numerical error.

20. The converter system of claim 17, wherein the converter system generates the first digital signal such that the analog output signal does not exceed the full-scale analog reference signal.
